(19) United States
(12) Patent Application Publication
(10) Pub. No.: US 2007/0107874 A1
(43) Pub. Date: May 17, 2007

(54) Water Cooling Type Heat Dissipation Apparatus with Parallel Runners

(76) Inventor: Yu-Huang Peng, Chung-Ho City (TW)

Correspondence Address: HDSL, 4331 STEVENS BATTLE LANE, FAIRFAX, VA, 22033, US

(21) Appl. No.: 11/532,955

(22) Filed: Sep. 19, 2006

(30) Foreign Application Priority Data
Nov. 11, 2005 (TW) 094219586

(51) Int. Cl. H05K 7/20

(52) U.S. Cl. 165/80.4; 361/699

(57) ABSTRACT

A water cooling type heat dissipation apparatus includes a heat dissipation stage having an upper cover and a lower cover. A first passageway and a second passageway extend from two ends of the upper cover. The upper cover includes a concave on inner side thereof. The lower cover includes a contact face and a heat conduction post arranged on inner bottom side of the lower cover. A plurality of heat dissipation fins is arranged on the heat conduction post and separated to each other to define parallel runners therebetween. Heat from heat source is absorbed by the contact face and conducted to the heat conduction fins through the heat conduction post. Liquid coolant flows into the parallel runners through the first passageway and resisted by the heat conduction post. Therefore, liquid coolant has sufficient heat exchange with the heat conduction fins and then exits through the second passageway.

### BACKGROUND OF THE INVENTION

1. Field of the Invention

The present invention relates to a heat dissipation structure, especially to a water cooling type heat dissipation structure for an electronic device.

2. Description of Prior Art

Heat generation is inevitable for any electronic device due to friction and efficiency problem. Some integrated circuits have serious heat dissipation problem for their compact size. Moreover, computer will generate more heat as the performance thereof is increased. Besides CPU, other components in computer such as chipset, graphic processor, DRAM and hard disk module will also produce considerable heat. Therefore, heat dissipation devices are necessary to remove heat from computer and to ensure normal operation of computer.

For example, electrical fan is often used as heat dissipation device and wind is generated by the electrical fan to remove heat from computer. However, the electrical fan can remove heat from a contact area between it and the heat generating element. Moreover, heat dissipation fins can also be attached to the surface of the heat generating element to increase the area for heat dissipation by electrical fan. However, the electrical fan can generated limited wind amount. Multiple electrical fans can be used to increase wind amount, however, it will occupy more space. Moreover, noise generates when the rotational speed of the electrical fan is increased.

Another prior art heat dissipation device is water cooling type heat dissipation device. A heat dissipation stage is arranged on the heat generating element such as CPU or hard disk. Liquid coolant is guided into the heat dissipation stage from a water tank by motor. The liquid coolant is heat exchanged with the heat generating element and the hot liquid coolant is cooled by a heat dissipation module and then flows back to the water tank. Therefore, heat can be removed from the heat generating element.

The liquid coolant has heat exchange with heat source and has better heat dissipation effect than air type heat dissipation device. However, the heat absorbing end of the heat dissipation stage is concentrated on the same place in above-mentioned prior art. Only part of the liquid coolant has heat exchange with the heat absorbing end. The liquid coolant remains in the heat dissipation stage for only very short time such that the liquid coolant exits through another channel before absorbing enough heat. FIG. 1 shows another prior art water cooling type heat dissipation device. The heat dissipation stage 101 is provided with a plurality of heat dissipation plates 102 arranged in upward and downward stagger fashion to form a single-direction runner. Therefore the liquid coolant stays longer when it flows through the staggering runner. The plurality of heat dissipation plates 102 increase heat dissipation area. However, the flow direction of the liquid coolant is parallel to the substrate of the heat dissipation stage. The liquid coolant flows out of the heat dissipation stage 101 soon and has not enough heat exchange with the heat dissipation plates 102.

### SUMMARY OF THE INVENTION

The present invention intends to provide a heat dissipation apparatus with multiple parallel runners defined by a plurality of heat dissipation fins and heat conduction post. Heat is absorbed by the heat conduction post and is conducted to the heat dissipation fins. Liquid coolant flows through the runners and is resisted by the heat conduction post. Therefore the liquid coolant stays longer in the runners and has sufficient heat exchange with the heat dissipation fins to enhance heat dissipation effect.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows another prior art water cooling type heat dissipation device.

FIG. 2 shows a top view of upper cover of the present invention.

FIG. 3 shows a top view of lower cover of the present invention.

FIG. 4 shows an exploded view of the present invention.

FIG. 5 shows the operation of the present invention.

FIG. 6 shows an exploded view of another preferred embodiment of the present invention.

FIG. 7 shows the operation of another preferred embodiment of the present invention.

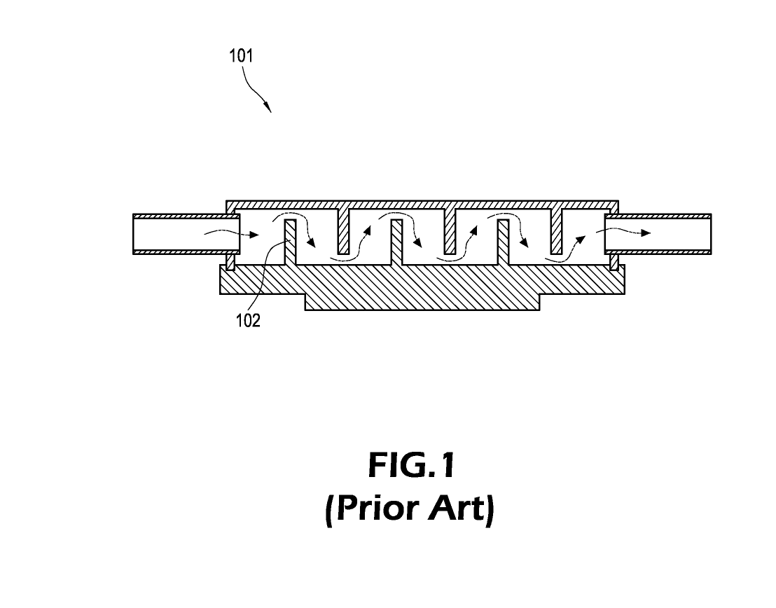

### DETAILED DESCRIPTION OF THE INVENTION

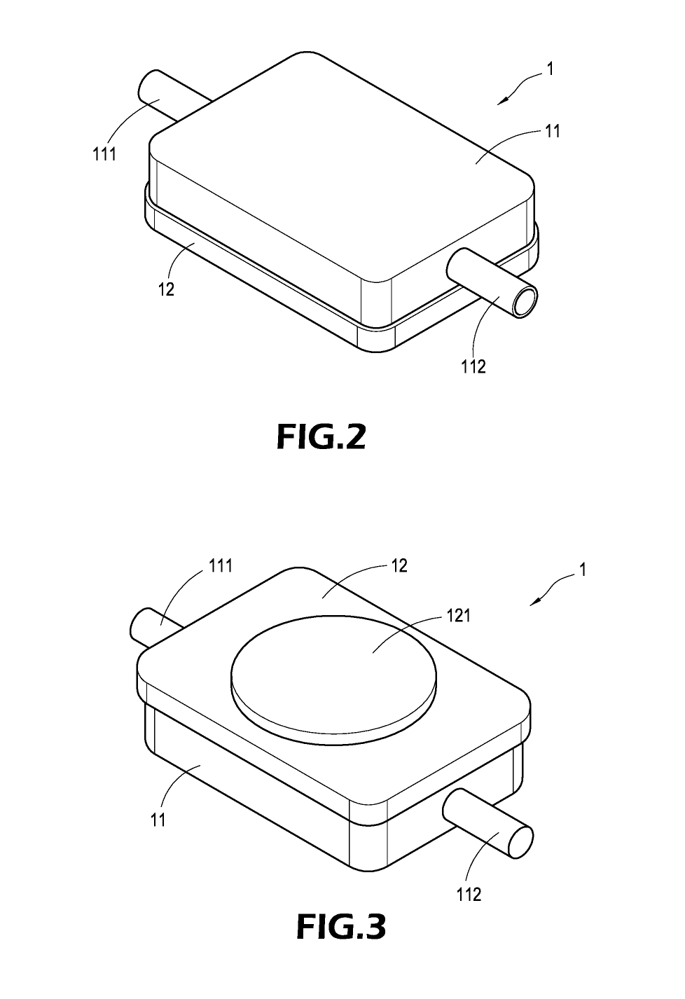

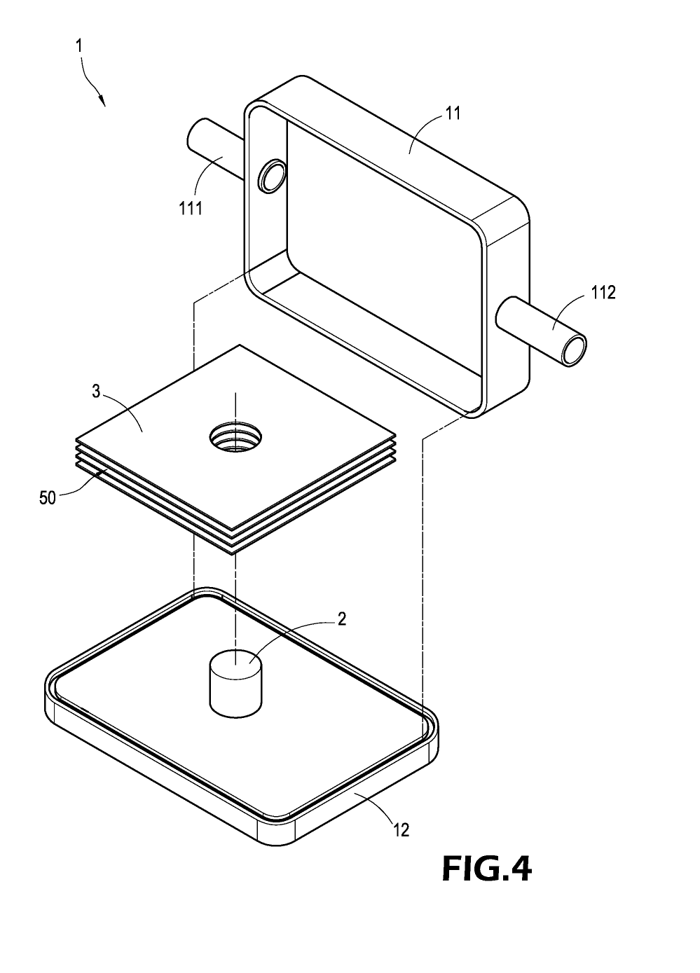

With reference to FIGS. 2 to 4, the heat dissipation stage 1 of the present invention comprises an upper cover 11 and a lower cover 12 to form a hollow closed box. The shape of the heat dissipation stage 1 of the present invention can be various according to practical need. In this shown preferred embodiment, the upper cover 11 and the lower cover 12 are of (but not limited to) rectangular shape, and made of heat conduction material such as metal or ceramics. The upper cover 11 and the lower cover 12 are assembled by soldering, riveting or bounding. Moreover, the upper cover 11 comprises a concave 113 on inner side thereof and a first passageway 111 and a second passageway 112 on left side and right side thereof (or upper side) for providing channel for liquid coolant to enter or exit the heat dissipation stage 1. The lower cover 12 comprises a contact face 121 on bottom side thereof and used for contacting the heat source.

The lower cover 12 comprises at leas one heat conduction post 2 on inner side thereof (only one in this embodiment). The heat conduction post 2 is made of heat conduction material such as metal or ceramics. In the preferred embodiment, the heat conduction post 2 is copper post. A plurality of heat dissipation fins 31 are arranged on the heat conduction post 2 and parallel to the lower cover 12 to form a heat dissipation fin set 3. A plurality of parallel runners 50 is defined between the plurality of heat dissipation fins 31 and parallel to each other. The heat dissipation fin set 3 can be also made of heat conduction material as that of the heat conduction post 2, and can be assembled through soldering, tightening or binding.

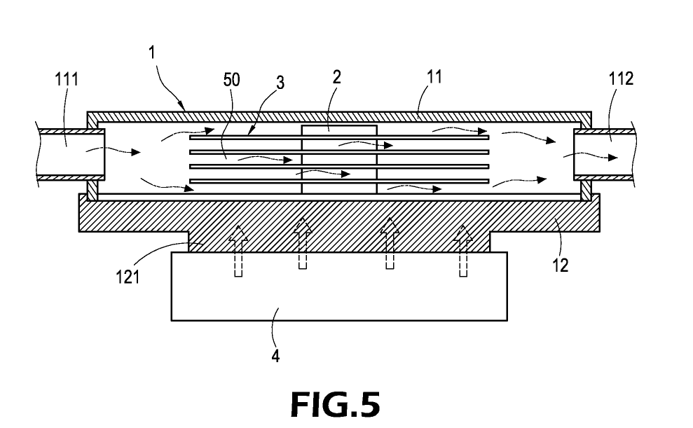

With reference to FIG. 5, when the upper cover 11 and the lower cover 12 is assembled to form the heat dissipation stage 1, the contact face 121 on bottom side of the lower cover 12 is attached to a heat generating element 4 (such as CPU or other heat generating chip). The heat generated by the heat generating element 4 is conducted to the heat conduction post 2 inside the heat dissipation stage 1 and then conducted to the heat dissipation fin set 3 through the heat conduction post 2. Afterward, liquid coolant (shown by arrow) is guided to the parallel runners 50 through the first passageway 111. The heat conduction post 2 provides flow resistant function to increase stay time of the liquid coolant. Therefore, the liquid coolant has sufficient heat exchange with the heat dissipation fin set 3 to absorb more heat from the heat generating element 4 and then the liquid coolant flows through the second passageway 112.

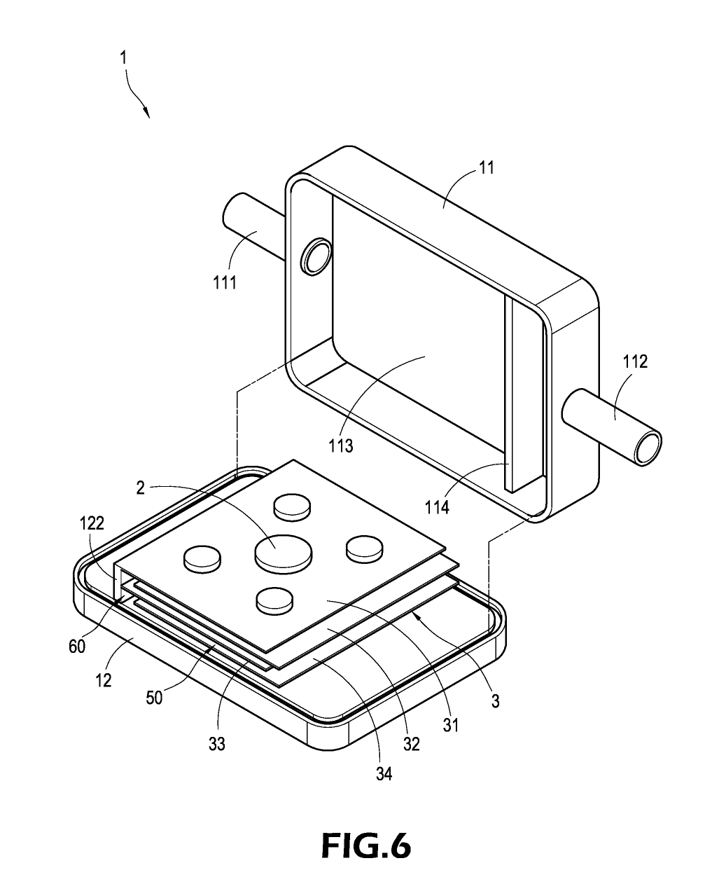

FIG. 6 shows the exploded view of another preferred embodiment of the present invention. There are a plurality of heat conduction posts 2 on the lower cover 12. A plurality of heat dissipation fins 31-34 are arranged on the heat conduction posts 2 and parallel to the lower cover 12 to form a heat dissipation fin set 3. A first baffle 122 is arranged vertically on the lower cover 12 and near the first passageway 111. First sides of the odd-layer heat dissipation fins 31 and 33 are vertically connected to the first baffle 122. The height of the first baffle 122 is even with top edge of the heat dissipation fin 31. First sides of the even-layer heat dissipation fins 32 and 34 have predetermined separation 60 with the first baffle 122. A second baffle 114 is arranged on the concave 113 and near the second passageway 112. When the upper cover 11 and the lower cover 12 are assembled, the second sides of the even-layer heat dissipation fins 32 and 34 are vertically connected to the second baffle 114, while the second baffle 114 has predetermined separation 60 with the second sides of the odd-layer heat dissipation fins 31 and 33. The bottom edge of the second baffle 114 is even with the fourth heat dissipation fin 34.

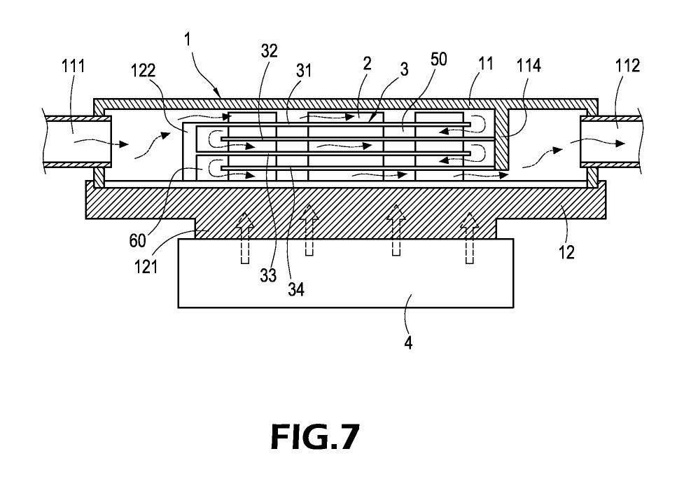

FIG. 7 shows the operation of the second preferred embodiment of the present invention. When liquid coolant (as shown by arrow) flows into the heat dissipation stage 1 through the first passageway 111, the liquid coolant is blocked by the first baffle 122 to flow toward parallel runners 50 defined by the first heat dissipation fin 31 and the upper cover 11. The liquid coolant then flows downward to parallel runners 50 defined by the first heat dissipation fin 31 and the second heat dissipation fin 32, where part of the liquid coolant is blocked by the second baffle 114 and then flows downward to the parallel runners 50. Therefore, the liquid coolant flows in parallel or downwardly through the plurality of runners defined by the heat dissipation fin set 3 until flows to the parallel runner 50 defined by the fourth heat dissipation fin 34 and the lower cover 12. Afterward the liquid coolant exits through the second passageway 112. Those parallel runners 50 are communicated to form a single-direction winding parallel runner 50. Therefore, the liquid coolant is resisted by the winding parallel runner 50 and the heat conduction post 2 to stay longer in the parallel runners 50. The heat of the heat generating element 4 is conducted to the heat dissipation stage 1 through the contact face 121 and conducted vertically to the heat dissipation fin set 3 through the heat conduction post 2. The heat is then heat-exchanged with the liquid coolant to achieve excellent heat dissipation effect. Moreover, the liquid coolant can also flows into the heat dissipation stage 1 through the second passageway 112 and then flows along the same parallel runners 50 but in reverse direction. Afterward the liquid coolant exits through the first passageway 111.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A water cooling type heat dissipation apparatus with parallel runners, comprising
a heat dissipation stage of a hollow box shape, which is used to contain liquid coolant and comprises a first passageway and a second passageway;
at least one heat conduction post arranged inside the heat dissipation stage and on an inner face of the heat dissipation stage; and
a plurality of heat dissipation fins arranged on the heat conduction post and separated to each other to define a plurality of parallel runners therebetween.

2. The water cooling type heat dissipation apparatus as in claim 1, wherein the heat dissipation stage further comprises:
a first baffle connected to first sides of odd-layer heat dissipation fins and having a first separation with first sides of even-layer heat dissipation fins; and
a second baffle connected to second sides of the even-layer heat dissipation fins and having a second separation with second sides of the odd-layer heat dissipation fins,
wherein the parallel runners are communicated through the first and the second separations to form a single-direction winding runner.

3. The water cooling type heat dissipation apparatus as in claim 1, wherein the heat dissipation stage comprises an upper cover and a lower cover.

4. The water cooling type heat dissipation apparatus as in claim 3, further comprising:
a first baffle arranged on the lower cover and connected to first sides of odd-layer heat dissipation fins and having a first separation with first sides of even-layer heat dissipation fins; and
a second baffle arranged on the upper cover and connected to second sides of the even-layer heat dissipation fins and having a second separation with second sides of the odd-layer heat dissipation fins;
wherein the parallel runners are communicated through the first and the second separations to form a single-direction winding runner.

5. The water cooling type heat dissipation apparatus as in claim 3, wherein the upper cover and the lower cover are made of heat conduction material.

6. The water cooling type heat dissipation apparatus as in claim 3, wherein the upper cover and the lower cover are made of metal or ceramics.

7. The water cooling type heat dissipation apparatus as in claim 3, wherein the upper cover and the lower cover are assembled through soldering, riveting or binding.

8. The water cooling type heat dissipation apparatus as in claim 1, wherein the heat dissipation stage comprises a contact face on bottom thereof.

9. The water cooling type heat dissipation apparatus as in claim 1, wherein the heat conduction post and the heat dissipation fins are made of heat conduction material.

10. The water cooling type heat dissipation apparatus as in claim 1, wherein the heat conduction post and the heat dissipation fins are made of metal or ceramics.

11. The water cooling type heat dissipation apparatus as in claim 1, wherein the heat conduction post and the heat dissipation fins are assembled through soldering, tightening or binding.

12. A water cooling type heat dissipation apparatus with parallel runners, comprising
a heat dissipation stage of a hollow box shape, which is used to contain liquid coolant and comprises a first passageway an a second passageway;
at least one heat conduction post arranged inside the heat dissipation stage and on inner face of the heat dissipation stage;
a plurality of heat dissipation fins arranged on the heat conduction post and separated to each other to define a plurality of parallel runners therebetween;
a first baffle arranged on lower inner face of the heat dissipation stage and connected to first sides of odd-layer heat dissipation fins and having a first separation with first sides of even-layer heat dissipation fins; and
a second baffle arranged on upper inner face of the heat dissipation stage and connected to second sides of the even-layer heat dissipation fins and having a second separation with second sides of the odd-layer heat dissipation fins;
wherein the parallel runners are communicated through the first and the second separations to form a single-direction winding runner.

13. The water cooling type heat dissipation apparatus as in claim 12, wherein the heat dissipation stage comprises a contact face on bottom thereof.

14. The water cooling type heat dissipation apparatus as in claim 12, wherein the heat conduction post and the heat dissipation fins are made of heat conduction material.

15. The water cooling type heat dissipation apparatus as in claim 12, wherein the heat conduction post and the heat dissipation fins are made of metal or ceramics.

16. The water cooling type heat dissipation apparatus as in claim 12, wherein the heat conduction post and the heat dissipation fins are assembled through soldering, tightening or binding.
